(19) United States
(12) Patent Application Publication
(10) Pub. No.: US 2014/0159758 A1
(43) Pub. Date: Jun. 12, 2014

(54) ASSEMBLY FOR OPTICAL BACKSIDE FAILURE ANALYSIS OF PACKAGE-ON-PACKAGE (POP) DURING ELECTRICAL TESTING

(71) Applicant: QUALCOMM INCORPORATED, San Diego, CA (US)

(72) Inventors: Himaja H. Bhatt, San Diego, CA (US); Martin E. Parley, Carlsbad, CA (US); Martin L. Villafana, Bonita, CA (US)

(73) Assignee: QUALCOMM INCORPORATED, San Diego, CA (US)

(21) Appl. No.: 13/712,634

(22) Filed: Dec. 12, 2012

(51) Int. Cl. G01R 1/04

(52) U.S. Cl. CPC G01R 1/0408
USPC 324/754.08; 324/756.02

(57) ABSTRACT

A method and apparatus for testing a package-on-package digital device is provided. The method includes the steps of: affixing a top device onto a wing board; affixing a bottom device onto the wing board; connecting the top side solderballs of the bottom package to the bond fingers of the wing board. The wing board is then mounted onto a flat top socket. Once the mounting has been completed, the testing begins, and may use a solid immersion lens or optical diagnostic tool. The configuration of the flat top socket and wing board allows the optical diagnostic tool full access to the bottom device for the testing process and failure analysis.

### BACKGROUND

1. Field

The present disclosure relates generally to testing electronic packages, and more particularly, package on package (POP) devices, which generally have a package mounted on top of another package.

2. Background

POP devices generally have a package mounted on top of another package. The two packages are electrically connected through any suitable connection. In the past, traditional sockets and failure analysis (FA) lids have been used to test POPs. This testing poses a problem when an optical diagnostic tool is used during failure analysis testing. In order for the optical diagnostic tool to fully analyze the bottom package under test it must come into physical contact with the bottom die in order to “see” the nano structures. These nano structures include devices such as transistors, resistors, and capacitors.

During testing the POP should be electrically connected, which is difficult as the top package blocks access to the bottom package. In addition, the conventional FA lid opening does not provide adequate space for the optical diagnostic tool to access the bottom die, as the optical diagnostic tool is too large to pass through the FA lid opening.

There is a need in the art for a flat-top socket and wing board to facilitate testing of POP devices. This assembly removes the top package and mounts it on a wing board that provides electrical connectivity while allowing access to the bottom die for the optical diagnostic tool testing.

### SUMMARY

Embodiments disclosed herein provide a method and apparatus for facilitating testing of a package-on-package device. The apparatus comprises a wing board having a pattern of pads for electrically connecting a top package to the pads of a bottom package as well as bond fingers for electrically connecting the package-on-package devices and a flat top socket with electrical contacts for electrically connecting wing board to a load board.

A further embodiment provides a method of testing a package-on-package device. The method includes the steps of: affixing a top package onto a wing board; affixing a bottom package onto the wing board; connecting the top side solderballs of the digital package to the bond fingers of the wing board. The wing board is then mounted onto a flat top socket. Once the mounting has been completed, the testing begins, and may use a solid immersion lens. The configuration of the flat top socket and wing board allows the optical diagnostic tool full access to the package on package device for the testing process and failure analysis.

Yet a further embodiment provides an apparatus for testing a package-on-package device. The apparatus comprises: means for affixing a top package onto a wing board; means for affixing a bottom package onto a wing board; means for connecting the top side solderballs of the bottom package to the bond fingers of the wing board; means for mounting the wing board onto a flat top socket; and means for testing the package-on-package device.

A still further embodiment provides a non-transitory computer readable medium containing instructions, which when executed by a processor, cause the processor to perform the steps of: activating an optical diagnostic tool; positioning the optical diagnostic tool over a package-on-package device reflowed onto a wing board and electrically connected to a flat top socket that in turn is connected to both the wing board and the load board; and accessing the package-on-package device with the optical diagnostic tool for testing.

### BRIEF DESCRIPTION OF THE DRAWINGS

FIG. 1 illustrates the problem of testing POP assemblies using a conventional testing FA lid and an optical diagnostic device.

FIG. 2 illustrates the flat-top socket and wing board according to an embodiment of the invention.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

POP devices typically have a memory package mounted on top of the digital package. The two packages are electrically connected through solder balls, just as the digital package connects with the socket. In the past, traditional FA lids have been used to test POPs. This has posed a problem when a solid immersion lens (SIL) or other optical diagnostic tool is used for failure analysis of the digital die because the optical diagnostic tool must come into contact with the die to “see” the nano structures such as transistors, resistors, capacitors, and other structures. The POP should be electrically connected during optical diagnostic testing, which poses a problem as the memory package blocks access to the bottom package. In addition, the typical FA lid does not provide sufficient space for the optical diagnostic tool to access the digital die because the optical diagnostic tool is too large to pass through the FA lid opening.

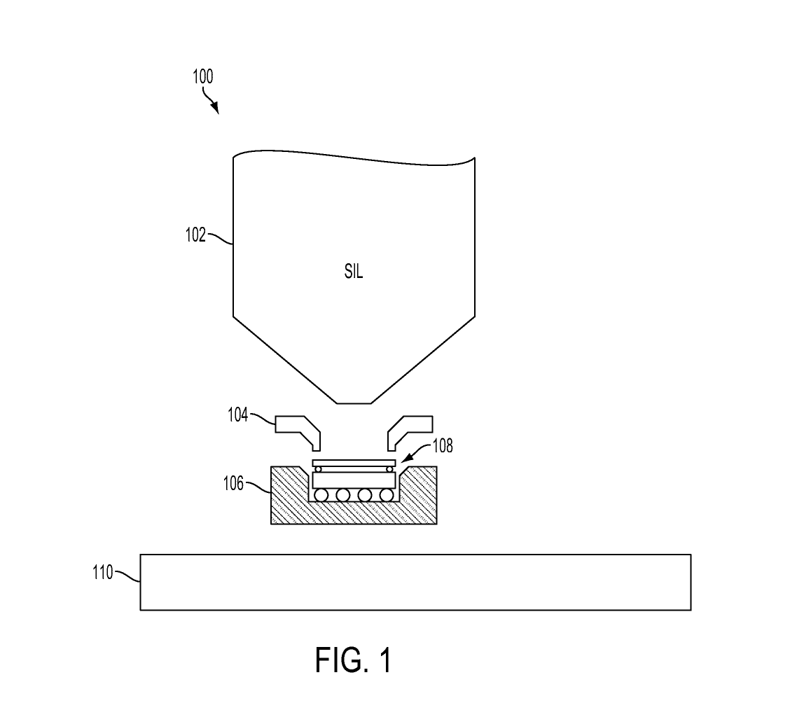

FIG. 1 illustrates the problem with using a conventional FA lid in conjunction with an optical diagnostic tool to test a POP. The test set up 100, shows a optical diagnostic tool 102 in relation to a conventional FA lid 104. The lid is placed on top of POP 108, which is in turn placed in conventional socket 106. Load board 110 is also used during testing.

Embodiments described herein provide a method and apparatus that overcomes the disadvantages of conventional testing methods and apparatus. Embodiments move the memory or top package to one side and allow the optical diagnostic tool access to the bottom digital die. The memory or top package is removed from the POP and mounted on a wing board. The wing board provides electrical connections with the digital package. The assembly does not require the conventional FA lid and permits the optical diagnostic tool to contact the digital die for testing.

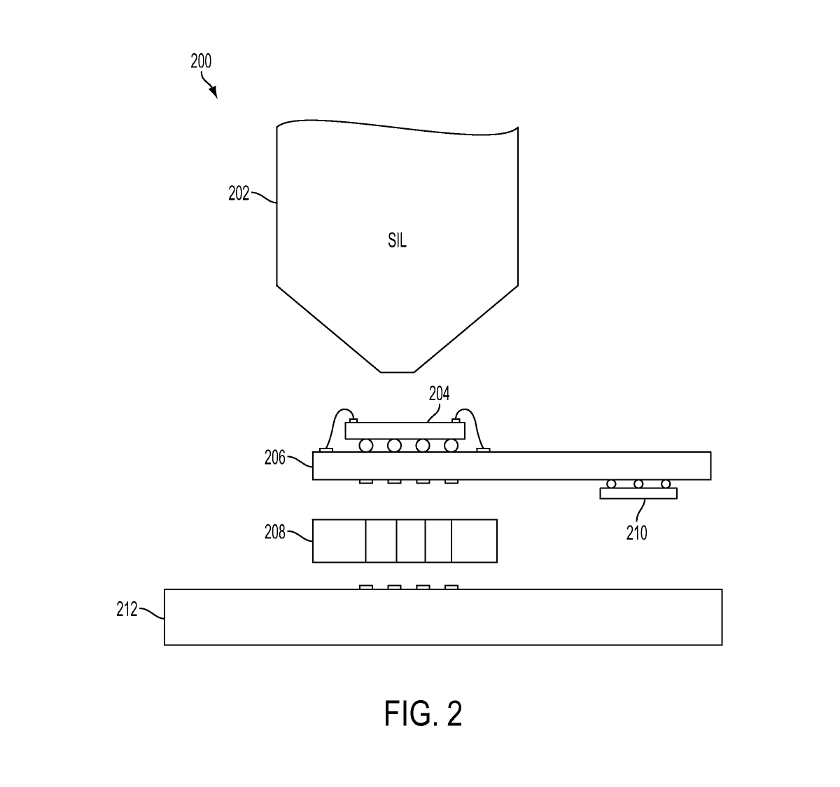

FIG. 2 illustrates the flat-top socket and wing board assembly 200 as viewed from the side during testing. The flat-top socket 208 replaces the conventional automated test equipment (ATE) socket. Flat-top socket 208 has a flat surface on top and does not provide a recess or pocket as an ATE socket provides. The digital die or package 204 is connected electrically to wing board 206. Memory package 210 is mounted to the underside, or second surface of wing board 206. Both digital die 204 and memory package 210 are electrically connected through solder balls to traces on wing board 206. Wing board 206 has pads for both the bottom digital package 204 and the top memory package 210. Digital package 204 and memory package 210 are reflowed or suitably affixed onto wing board 206 using conventional reflow solder techniques, however, any suitable technique may be used. The top side solder balls of the digital package 204 are bonded to wing board 206 bond fingers. Wing board 206 includes internal traces that connect the board fingers to the top or memory package 210 fingers to memory package 210 pads to provide an electrical connection. The wing board 206 is then mounted on flat top socket 208 using any suitable mounting method Because there is no FA lid to interfere, optical diagnostic tool 202 may make direct contact with the digital die 204. Flat-top socket 208 is in electrical contact with load board 212.

Wing board 206 has pads for digital package 204 and pads for memory package 210. The digital package 204 and memory package 210 are reflowed or affixed onto the wing board 206. The toe side solder balls of the digital package 204 are wire bonded or electrically connected to the fingers on wing board 206. The wing board 206 includes internal traces that connect the board's fingers to the memory package 210 pads to form an electrical connection.

An alternative embodiment provides that the top memory package 210 may be mounted to one side on wing board 206, instead of on the underside, as depicted in FIG. 2.

The interface between wing board 206 and ATE load board 212 may be accomplished by several methods, including flat-top socket, flip-chip socket, elastomer, or other suitable method.

The embodiment described above provides numerous advantages over conventional techniques. No direct pressure is applied to the thinned package, which has had the protective lid removed, thus preventing die cracking. In addition, there is no FA lid to apply pressure and obstruct SIL access to the digital device under test as the memory package has been moved to the wing board. The original load board and socket may be used without modification, allowing for cost saving and avoiding duplication of dedicated failure analysis boards.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. An apparatus for facilitating testing of a package-on-package digital device, comprising:
a wing board having a pattern of pads for electrically connecting a top device to pads for a bottom device and bond fingers for electrically connecting to the package-on-package device; and
a flat top socket having pads for electrically connecting wing board to a load board.

2. A method of testing a package-on-package digital device, comprising:
affixing a top device to a wing board;
affixing a bottom device to the wing board;
connecting top side solderballs of the bottom device to bond fingers on the wing board;
mounting the wing board onto a flat top socket; and
testing the bottom device.

3. The method of claim 2, where the testing uses an optical diagnostic tool.

4. The method of claim 2, wherein the top device is mounted on a same surface of the wing board as the digital device.

5. The method of claim 2, wherein the top device is mounted on an opposite surface of the wing board as the digital device.

6. An apparatus for testing a package-on-package digital device, comprising:
means for affixing a top device onto a wing board;
means for affixing a bottom device onto a wing board;
means for connecting top side solderballs of the digital package to bond fingers on the wing board; and
means for mounting the wing board onto a flat top socket; and means for testing the package-on-package digital device.

7. The apparatus of claim 6, wherein the means for testing uses an optical diagnostic tool.

8. The apparatus of claim 6, wherein the means for reflowing a top device on the wing board reflows the bottom device on a same surface of the wing board as the top device.

9. The apparatus of claim 1, further comprising:
an interface between the wing board and the load board.

10. The apparatus of claim 1 wherein the interface between the wing board and the load board is a flat top socket.

11. The apparatus of claim 9, wherein the interface between the wing board and the load board is a flip chip socket.

12. The apparatus of claim 9, wherein the interface between the wing board and the load board is an elastomer.

13. A non-transitory computer readable medium containing instructions, which when executed by a processor cause the processor to perform the steps of:
activating an optical diagnostic tool;
positioning the optical diagnostic tool over a bottom device reflowed onto a wing board and electrically connected to a flat top socket in turn electrically connected to a wing board and a load board; and
accessing the bottom device for testing using the optical diagnostic tool.
